(19) United States
(12) Patent Application Publication
(10) Pub. No.: US 2025/0198002 A1
(43) Pub. Date: Jun. 19, 2025

(54) GAS HUB FOR MULTI-STATION WAFER PROCESSING SYSTEM

(71) Applicant: Eugenus, Inc., San Jose, CA (US)

(72) Inventors: Sangdon Lee, Seoul (KR); Changhun Shin, Seoul (KR); Michael Tu, Fremont, CA (US); Meihua Zhang, Jr., San Jose, CA (US); Amir Kiaee, Los Gatos, CA (US)

(21) Appl. No.: 18/544,202

(22) Filed: Dec. 18, 2023

(51) Int. Cl. C23C 16/455

(52) U.S. Cl. CPC C23C 16/45591; C23C 16/45561; C23C 16/45544

(57) ABSTRACT

The disclosed technology relates generally to semiconductor manufacturing, and more particularly to precursor delivery in cyclic deposition. A thin film deposition system comprises a manifold assembly to receive a gas from an inlet line and delivery the gas to a plurality of thin film processing stations through respective outlet lines. The manifold assembly comprises an internal hub reservoir with a base diameter significantly greater than an internal channel diameter of the inlet line. The hub reservoir lacks rotationally symmetry when rotated about 360° around the center. The inlet line is located below an uppermost surface of the hub reservoir and delivers the gas into the hub reservoir a vertically in a central region. The plurality of outlet lines are about evenly, radially distributed around the circumference of the hub reservoir.

### BACKGROUND

### Field

The disclosed technology relates generally to semiconductor manufacturing, and more particularly to a gas hub for a multi-station wafer processing system.

### Description of the Related Art

Semiconductor fabrication involves various fabrication processes that employ various types of gases throughout the process flow. The various fabrication processes can include, for example, etch processes that use reactive gases and deposition processes that use precursors, to name a few. The various fabrication processes rely on within-wafer and wafer-to-wafer uniformity of gas delivery that may be critical for achieving high manufacturing reliability and yield.

Various thin films can be deposited using different techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods include precursor and/or chemical reaction-based techniques, e.g., chemical vapor deposition (CVD) and cyclic deposition such as atomic layer deposition (ALD).

Cyclic deposition processes such as atomic layer deposition (ALD) processes can provide relatively conformal thin films on relatively high aspect-ratio structures with high uniformity and thickness precision. ALD can be used to deposit a variety of different films including elemental metals, metallic compounds (e.g., TiN, TaN), semiconductors (e.g., Si, III-V), dielectrics (e.g., SiO₂, AlN, HfO₂, ZrO₂), rare-earth oxides, conducting oxides (e.g., IrO₂), ferroelectrics (e.g., PbTiO₃, LaNiO₃), superconductors (e.g., YBa₂Cu₃O₇₋ₓ), and chalcogenides (e.g., GeSbTe), to name a few. During an ALD process a substrate is alternatingly exposed to a plurality of precursors to form a thin film. The different precursors can alternatingly at least partially saturate the surface of the substrate and react with each other, thereby forming the thin film in a layer-by-layer fashion. Because of the layer-by-layer growth capability, ALD can enable precise control of the thickness and the composition, which in turn can enable precise control of various properties such as conductivity, conformality, uniformity, barrier properties and mechanical strength. The nature of the deposition process has led the precursor delivery systems of ALD deposition systems to be uniquely constructed. For example, because a specific thin film on a substrate is formed from repeatedly exposing the substrate to multiple precursors at a relatively high speed and/or at a relatively high frequency, precursor delivery systems or components thereof, such as precursor delivery lines, valves and manifolds can directly or indirectly pose significant limitations to various aspects of the ALD deposition process, including precision, uniformity, throughput, reliability and operating cost thereof.

### SUMMARY

In a first aspect, a gas hub manifold assembly for delivering a gas to a multi-station wafer processing system includes a hub reservoir fluidically connected to and between a gas source and a plurality of wafer processing stations. The manifold assembly additionally includes an inlet connected to the hub reservoir and configured for receiving the gas into the hub reservoir in an axial direction. The manifold assembly additionally includes a plurality radially directed outlet lines connected to the hub reservoir and configured for delivering the gas to the wafer processing stations surrounding the hub reservoir. An internal reservoir volume of the hub reservoir lacks rotational symmetry when the hub reservoir is rotated about a central axis of the hub reservoir by any angle less than 360°.

In a second aspect, a gas hub manifold assembly for delivering a gas to a multi-station wafer processing system includes a hub reservoir fluidically connected to and between a gas source and a plurality of wafer processing stations. The manifold assembly additionally includes an inlet connected to the hub reservoir and configured for receiving the gas into the hub reservoir in an axial direction, wherein an internal reservoir volume of the hub reservoir has an uppermost surface and the inlet is configured to introduce the gas at a lower vertical level below the uppermost surface. The manifold assembly further comprises a plurality of radially directed outlet lines connected to the hub reservoir and configured for delivering the gas to the wafer processing stations surrounding the hub reservoir.

In a third aspect, a gas hub manifold assembly for delivering a gas to a multi-station wafer processing system includes a hub reservoir fluidically connected to and between a gas source and a plurality of wafer processing stations and provides an internal reservoir volume of at least 10,000 mm³. The manifold assembly additionally includes an inlet connected to the hub reservoir and configured for receiving the gas into the hub reservoir in an axial direction. The manifold assembly further includes a plurality radially directed outlet lines connected to the hub reservoir and configured for delivering the gas to the wafer processing stations surrounding the hub reservoir.

### BRIEF DESCRIPTION OF THE DRAWINGS

Specific implementations will now be described with reference to the following drawings, which are provided by way of example, and not limitation.

The patent or application file contains at least one drawing executed in color. Copies of this patent or patent application publication with color drawing(s) will be provided by the Office upon request and payment of the necessary fee.

FIG. 1 schematically illustrates a thin film deposition system including a thin film deposition chamber and a precursor delivery system configured with precursor delivery lines.

FIG. 2 shows a perspective view of a top external portion of a thin film deposition system including a stack of gas hub manifold assemblies connected to and between precursor sources and multiple wafer processing stations.

FIG. 3A shows a perspective view of a baseline model manifold assembly connecting one inlet line to four outlet lines for gas distribution.

FIG. 3B shows a perspective cross-sectional view of the baseline model manifold assembly illustrated in FIG. 3A revealing a side cross-sectional view of the inlet line and a vertical portion of the inlet line connecting outlet lines.

FIG. 3C shows a top-down cross-sectional view of the baseline model manifold assembly illustrated in FIG. 3A revealing the four outlet lines connected together.

FIG. 3D shows a side perspective cross-sectional view of the baseline model manifold assembly illustrated in FIG. 3A revealing a vertical portion of the inlet line connecting two outlet lines.

FIG. 4 illustrates a simulated fluid velocity distribution inside the inlet line and two outlet lines of the baseline manifold assembly illustrated in FIGS. 3A-3D.

FIG. 5A shows a perspective view of an internal volume of a manifold assembly having a hub reservoir connecting one inlet line to four outlet lines for gas distribution, according to embodiments.

FIG. 5B shows a top view of the internal volume of the manifold assembly illustrated in FIG. 5A.

FIG. 5C shows a side cross-sectional view of the internal volume of the manifold assembly illustrated in FIG. 5A revealing an internal structure of the hub reservoir.

FIG. 6A shows a perspective view of an internal volume of a manifold assembly having an asymmetric internal hub reservoir volume connecting one inlet line to four outlet lines for gas distribution, according to embodiments.

FIG. 6B shows a top view of the internal volume of the manifold assembly illustrated in FIG. 6A.

FIG. 6C shows a side cross-sectional view the manifold assembly illustrated in FIG. 6A revealing an internal structure of the asymmetric hub reservoir.

FIGS. 7A-7I show various manifold assemblies each having unique design configurations, according to various embodiments.

FIGS. 8A-8C illustrate different sectional views of simulated fluid velocity distributions inside the inlet line and two outlet lines of a manifold assembly according to embodiments.

FIG. 9A illustrates curves of mass flow rate profile with time for the four outlet lines of the baseline manifold assembly illustrated in FIGS. 3A-3D.

FIG. 9B illustrates curves of mass flow rate profile with time for the four outlet lines of the manifold assembly illustrated in FIGS. 5A-5C.

FIG. 10 illustrates a stack of manifold assemblies with each of the manifold assembly connecting one inlet line to four outlet lines to distribute a gas.

### DETAILED DESCRIPTION

Semiconductor manufacturing involves various fabrication processes that employ various types of gases throughout the process flow. The various fabrication processes can include, for example, etch processes that use reactive gases and deposition processes that use precursors, to name a few. The various fabrication processes rely on within-wafer and wafer-to-wafer uniformity of gas delivery that may be critical for achieving high manufacturing reliability and yield.

Among different fabrication processes, examples of deposition processes that rely on high precision gas delivery include chemical vapor deposition (CVD) and atomic layer deposition (ALD). In addition to the high precision, the advancement in semiconductor manufacturing technologies demands ever-increasing throughput. By way of example, growing a thin film on a substrate in ALD may involve from a few to as many as thousands or even more of cycles of alternating exposures to different gaseous precursors. The number of cycles, cycle durations and frequencies of the alternating exposures of the substrate to multiple precursors is directly related to throughput. The number of cycles, durations and frequencies of the exposures to precursors can in turn be limited by the precursor delivery system or components thereof, such as precursor delivery line and manifold configurations. In particular, the conductance (e.g., capacity to hold and provide precursor), fluid resistance, and fluid pressure distribution within the precursor delivery lines and manifolds can directly impact the deposition throughput, the efficiency of precursor usage, and the quality of the resulting thin film, e.g., consistency and uniformity.

For increased throughput, some processing systems include multiple thin film or wafer processing stations or chambers that may be nominally configured to be identical to each other. However, various factors may give rise to station-to-station or chamber-to-chamber variability. For example, a gas manifold may be configured for supplying a gas to multiple stations at different times. However, supplying the gas to one station may affect the supply condition of the gas delivery to another station. For example, a pressure drop caused by supplying the gas to one station may affect the supply pressure to another station. Thus, there is a need for improved precursor delivery systems including gas manifolds for optimal precursor delivery speed and uniformity, and thin film forming throughput, quality, conformality and uniformity.

### Multi-Station Wafer Processing Systems

To address the above-mentioned needs among others, a semiconductor processing system includes a gas hub manifold assembly for delivering a gas to multiple wafer processing stations. For example, a thin film deposition system may include a plurality of deposition stations or chambers each configured to deposit a thin film by alternatingly exposing a substrate to a plurality of gaseous precursors. The thin film deposition system further comprises a source of a gaseous fluid (e.g., precursor source) connected to the thin film deposition chamber by a precursor delivery line.

For deposition systems configured for multi-stations, station-to-station matching poses a challenge for achieving high manufacturing precision and yield. The gas hub manifold plays a key role in delivering process gases to each of the multiple (e.g., four) stations. In general, a gas hub manifold design takes into consideration various process criteria. These criteria include gas uniformity, gas distribution capability, gas hub weight and gas hub height, to name a few. Among those, gas uniformity may be the most important criteria.

The inventors have found, among other things, that limited gas volume in the gas hub manifold can be an issue. If the fluid domain volume in the hub is too small, process gas may not mix sufficiently before it is delivered to different stations, which can contribute to non-uniformity. In addition, insufficient internal volume can cause a significant pressure to drop in the internal volume when one or more of station valves (e.g., ALD valves) are opened.

To address these and other concerns, gas hub manifolds disclosed herein may comprise an increased internal reservoir volume serving as an intermediate precursor reservoir disposed between the precursor source and the thin film deposition chamber. The configurations allow for higher dosage of each precursor per cycle that the substrate in the process chamber is exposed to, which in turn can lead to a substantial reduction in precursor exposure time to reach substantial substrate surface saturation by the specific precursor. The configurations also allow for increased consistency and stability of the precursors delivered into the process chamber. For example, the configurations allow for increased dosage with reduced pressure fluctuation in the delivery lines by providing an intermediate precursor reservoir serving as a buffer between the precursor sources and the thin film deposition chamber. Thus, gas hub configurations described herein can be especially advantageous for a thin film deposition system having multiple processing stations, which can use much higher amounts of the precursors and purge gases than a thin film deposition chamber having a single processing station. The increased dosages and consistency of the precursors delivered by the precursor delivery system according to embodiments advantageously enables improved step coverage and consistency across the processing stations for the thin film forming, especially when the substrates have high aspect ratio structures on the uppermost surfaces where the thin films are formed.

The inventors have further found that symmetric gas hub designs may not provide an optimum solution under some circumstances, even when the gas outlet lines are symmetrically positioned. Some gas hub designs use internally symmetric volumes, with the aim of achieving higher station-to-station uniformity. To inventors' surprise, internally symmetric gas hub designs may not necessarily provide uniform delivery of process gases to each of the stations, due in part to the fact that the gas inlet comes from one axial direction and the complex and unintuitive flow pattern in the gas hub manifold caused by the directional gas entrance.

Gas uniformity is related to the fluid domain volume. However, the relationship between the volume and gas uniformity may not be nonlinear. In addition, many gas hub manifolds are using different size gas hubs for different process gases, which can increase the difficulty in manufacturing. Thus, designing an optimized gas hub manifold has remained a challenge.

To address these and other various challenges faced in a gas hub manifold assembly design for a multi-station wafer processing system, a gas hub manifold assembly according to embodiments includes a hub reservoir fluidically connected to and between a gas source and a plurality of wafer processing stations. The manifold assembly additionally includes an inlet connected to the hub reservoir and configured for receiving the gas into the hub reservoir in an axial direction. The manifold assembly additionally includes a plurality of radially directed outlet lines connected to the hub reservoir and configured for delivering the gas to the wafer processing stations surrounding the hub reservoir.

In some embodiments, an internal reservoir volume of the hub reservoir lacks rotational symmetry when the hub reservoir is rotated about a central axis of the hub reservoir by any angle less than 360°.

In some other embodiments, an internal reservoir volume of the hub reservoir has an uppermost surface, and the inlet is configured to introduce the gas at a lower vertical level below the uppermost surface.

In some other embodiments, a hub reservoir provides an internal reservoir volume of at least 10,000 mm³.

In the following, embodiments may be described using specific example precursors. For example, specific example precursors including titanium tetrachloride (TiCl₄), ammonia (NH₃) and dichlorosilane (SiCl₂H₂) for depositing titanium nitride (TiN) and/or titanium silicon nitride (TiSiN) may be used to describe the thin film deposition system and a method of depositing a thin film using the thin film deposition system. However, it will be understood that embodiments are not limited to the example precursors, and the inventive aspects can be applied to any suitable combinations of gases, e.g., precursors, for depositing any suitable thin film that can be formed using cyclic deposition processes such as ALD.

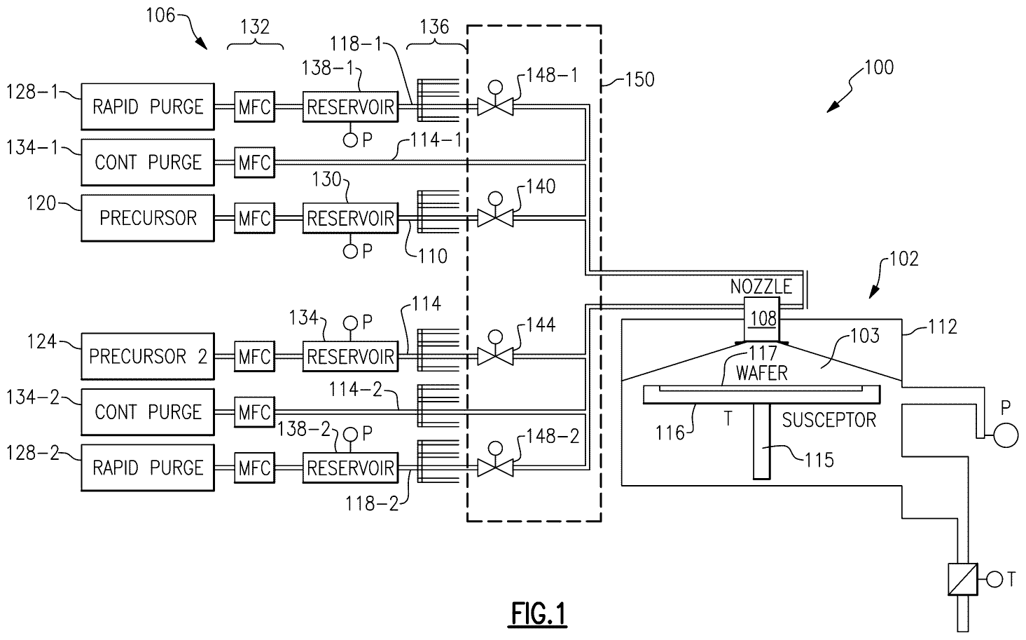

FIG. 1 schematically illustrates a thin film deposition system 100, according to embodiments. The thin film deposition system 100 includes at least one thin film processing station 102 each having a deposition chamber 103 therein, and a precursor delivery system 106 configured to deliver a plurality of precursors into the deposition chamber 103. The illustrated deposition chamber 103 is configured to process a substrate 117, e.g., a 300 mm wafer or a 400 mm wafer, on a support 116, e.g., a susceptor, that is supported by a supporting post 115, under a process condition. The deposition chamber 103 additionally includes a nozzle 108 configured to centrally discharge the plurality of precursors into the deposition chamber 103 through a gas distribution plate 112, also referred to as a showerhead. The nozzle 108 may mix gases, e.g., a precursor and a purge gas, prior to being diffused into the deposition chamber 103 by the gas distribution plate 112. The gas distribution plate 112 is configured to uniformly diffuse the precursor(s) over the substrate 117 on the susceptor 116 so that a uniform deposition occurs over the substrate 117. The deposition chamber 103 may be equipped with pressure monitoring sensors (P) and/or temperature monitoring sensors (T).

The precursor delivery system 106 is configured to deliver a plurality of precursors from precursor sources 120, 124 and one or more purge gases, e.g., inert gases, from purge gas sources 128-1, 128-2, 134-1, 134-2 into the deposition chamber 103. Each of the precursors and purge gases is connected to the deposition chamber 103 by a respective gas delivery line. Advantageously, at least some of the gas delivery lines can comprise increased conductance line portions 130, 134, 138-1, 138-2 serving as intermediate gas reservoirs between the precursor or purge gas sources and the thin film deposition chamber 103. The gas delivery lines may additionally include in their paths mass flow controllers (MFCs) 132, gas hub manifolds 136, and respective precursor valves 140, 144, 148-1, and 148-2 of the valve block assembly 150 for introducing respective precursors into the thin film deposition chamber 103. Each of the gas hub manifolds receives a gas, e.g., a precursor or a purge gas, from the respective increased conductance portion 130, 134, 138-1, 138-2 and delivers the gas to multiple processing stations, one of which is the processing station 102. Further advantageously, at least some of the valves can be atomic layer deposition (ALD) valves. The gas delivery lines are connected to the deposition chamber 103 through the gas distribution plate 112 of the processing station 102.

For illustrative purposes only, in the illustrated configuration of FIG. 1, the plurality of precursors include a first precursor (e.g., Prec. 1) and a second precursor (e.g., Prec. 2). The first precursor is stored in at least one first precursor source 120, and the second precursor is stored in at least one second precursor source 124. The precursor delivery system 106 is configured to deliver the Prec. 1 and Prec. 2 from the first and second precursor sources 120, 124 into the deposition chamber 103 through first and second precursor delivery lines 110, 114, respectively. The first and second precursor delivery lines 110, 114 include the high conductance line portions 130, 134, respectively. A rapid purge (RP) gas can be stored in at least two RP gas sources 128-1, 128-2. The precursor delivery system 106 is configured to deliver the RP gas from the RP gas sources 128-1, 128-2 into the deposition chamber 103 through respective RP gas delivery lines 118-1, 118-2. The RP gas delivery lines 118-1, 118-2 include the high conductance line portions (or reservoirs) 138-1, 138-2, respectively. Further, a continuous purge (CP) gas can be stored in at least two CP gas sources 134-1, 134-2. The precursor delivery system 106 is configured to deliver the CP gas from the CP gas sources 134-1, 134-2 into the deposition chamber 103 through respective CP gas delivery lines 114-1, 114-2.

The Prec. 1 and Prec. 2 are configured to be delivered from the first and second precursor sources 120, 124, respectively, by independently actuating the first and second precursor atomic layer deposition (ALD) valves 140 and 144 that are connected in parallel to deliver the Prec. 1 and Prec. 2 to the deposition chamber 103 through the common gas distribution plate 112. Additionally, the RP purge gas is configured to be delivered from the RP purge gas sources 128-1, 128-2 by independently actuating the two respective purge gas ALD valves 148-1, 148-2 that are connected in parallel to deliver the RP purge gas to the deposition chamber 103 through the common gas distribution plate 112. The ALD valves 140, 144, 148-1 and 148-2 and the respective delivery lines connected to the gas distribution plate 112 can be arranged to feed the respective gases into the nozzle 108 through the multivalve block assembly 150, which may be located adjacent to the processing station 102. In the illustrated configuration, the ALD valves 140, 144, 148-1 and 148-2 are final control valves before the respective gases are introduced into the deposition chamber 103 of the processing station 102.

By way of example only, the Prec. 1 and Prec. 2 can include TiCl₄ and NH₃, respectively, that are delivered into the deposition chamber 103 from respective TiCl₄ and NH₃ sources through respective precursor delivery lines to form, e.g., TiN, thin film on a substrate, e.g., a wafer. The precursor delivery system can additionally be configured to deliver Ar as the purge gas into the process chamber 103 from Ar sources through purge gas delivery lines. Purge gases may be delivered as a continuous purge (CP) gas, which may be delivered with or without precursor ALD valves, and/or as a rapid purge (RP) gas, which may be delivered through dedicated purge gas ALD valves as shown in FIG. 1. The illustrated precursor delivery system 100 can be configured to deliver Ar as an RP gas into the deposition chamber 103 from the purge gas sources 128-1, 128-2 through respective purge gas delivery lines and purge gas ALD valves 148-1, 148-2.

According to various embodiments, the thin film deposition system 100 of FIG. 1 can be configured for thermal ALD without the aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relative high aspect ratios. Without being limited by theory, one possible reason for this is that plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

In some embodiments, the thin film deposition system 100 can be configured to provide increased flow and stability of the precursors delivered into the deposition chamber 103 in part due to the presence of the high conductance line portions 130, 134, 138-1, 138-2 of the delivery lines. The inventors have discovered that achieving short precursor exposure times without sacrificing stability can be particularly difficult for delivery systems having multiple processing stations as described herein (e.g., FIG. 2), due the higher combined volumes of precursors that are delivered to the multiple processing stations.

FIG. 2 shows an example deposition system in which various embodiments can be implemented. In FIG. 2, a perspective view of a top external portion of a deposition system 200 is illustrated to include multiple (e.g., four) processing stations each configured to deliver a precursor therein for thin film deposition, according to embodiments. Each processing station is configured, e.g., in a similar manner as described above with respect to FIG. 1, and comprises a respective distribution plate. Referring back to FIG. 1, after a respective one of the MFCs, each of the gas delivery lines branches off into multiple lines at a respective gas hub manifold 136. Each of the branched off lines can feed a respective gas into one of the processing stations. The illustrated process system 200 comprises one or more processing stations each configured to process a substrate on a support, e.g., a susceptor, under a process condition, in a similar manner as described above with respect to FIG. 1. In some embodiments, each of the processing stations may be configured to process a substrate under a unique process condition, including a process temperature and a process pressure. In the illustrated embodiment, there are four processing stations having corresponding distribution plates (e.g., showerheads) 112-1, 112-2, 112-3, 112-4. The distribution plates 112-1, 112-2, 112-3, 112-4 have attached thereon, at central locations thereof respective ones of multivalve blocks 250-1, 250-2, 250-3, 250-4. In addition, gas lines for delivering the same gas to the multivalve blocks 250-1, 250-2, 250-3, 250-4 branch off from common gas hub manifolds 136 as shown, similar to the gas hub manifolds 136 described above with respect to FIG. 1. In FIG. 2, a stack of gas hub manifolds 136 are located at a central region of the top portion of the deposition system 200, surrounded by the multiple distribution plates 112-1, 112-2, 112-3, 112-4 of the respective processing stations. The illustrated deposition system 200 is thus configured to, for each processing station, introduce one or more precursors using two or more atomic layer deposition (ALD) valves each configured to supply a precursor and/or a purge gas, according to embodiments.

### Gas Hub Manifold Assemblies for Multi-Station Wafer Processing Systems

One of the objectives of the precursor delivery system 106 illustrated in FIG. 1 is to deliver the precursors and the purge gases to a plurality of processing stations with temporal and spatial uniformity. In the context of this disclosure, temporal uniformity refers to uniformity of gas delivery over time, e.g., during a deposition phase of an ALD cycle, and inter-station uniformity refers to uniformity of gas delivery across multiple stations or chambers therein. Higher temporal uniformity of dosage delivered to a deposition chamber in a processing station refers to lower flow rate change over time, while higher inter-station uniformity of dosages delivered to two processing stations means that less difference exists between the two dosages delivered. The pressure in each of the precursor sources 120, 124 and rapid purge (RP) gas sources 128-1, 128-2 in FIG. 1 can be controlled according to measurements of the respective pressure monitoring sensor P coupled to respective line portions. For illustrative purposes only, the sensor P is coupled to the high conductance line portion 130, 134, 138-1, or 138-2, for the arrangement shown in FIG. 1. Each of the high conductance line portions 130, 134, 138-1, 138-2 can be configured to have a high enough volume capacitance to serve as an intermediate reservoir for a respective precursor or RP gas. As such, the precursors or RP gases are delivered to the respective gas hub manifolds, or simply manifolds, with steady pressure and by large flow rate capacity to satisfy the temporal and spatial dosage requirement. Similarly, the continuous purge (CP) gases from the CP sources 134-1, 134-2 shown in FIG. 1 can be configured to deliver gaseous fluid to the respective manifolds with steady pressure.

As shown in FIG. 2, each of the gases passes through a respective gas hub manifold assembly. At each manifold assembly 136, the gas, being one of the precursors, one of the RP gases or the CP gases, may be split into a plurality of outlet lines. A plurality of the manifold assemblies 136 are stacked together to form a stack of manifold assemblies. Such design simplifies the delivery design for multiple gases over designs in which separate stations have their own delivery lines for each station. Among other effects, the manifold assembly 136 with ample internal reservoir volume is configured to improve the temporal and station-to-station uniformity of gas delivery, such that the gas from the inlet line is equally and consistently divided and sent to the plurality of outlet lines so that each deposition chamber or processing station connected to one of the plurality of the outlet lines receives about equal volume or dosage of the gas.

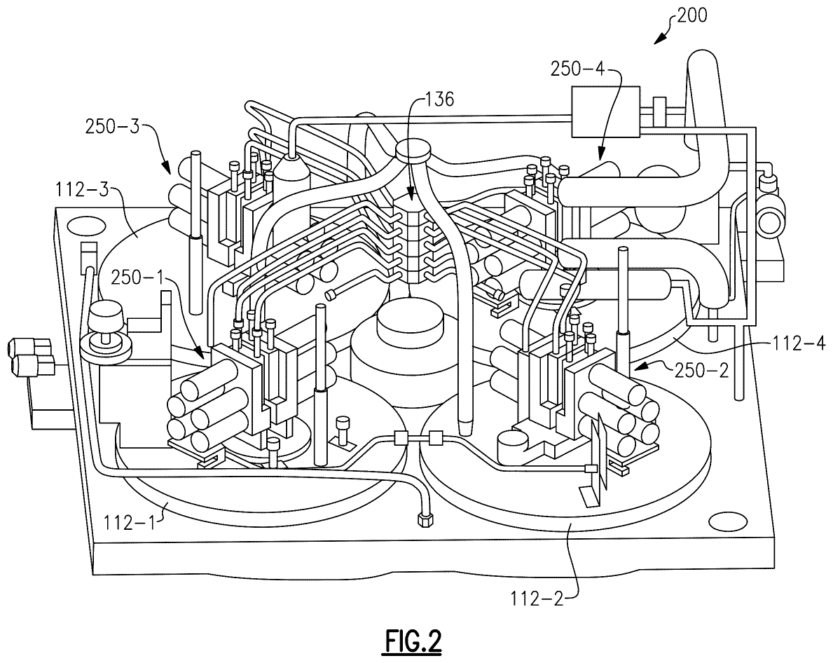

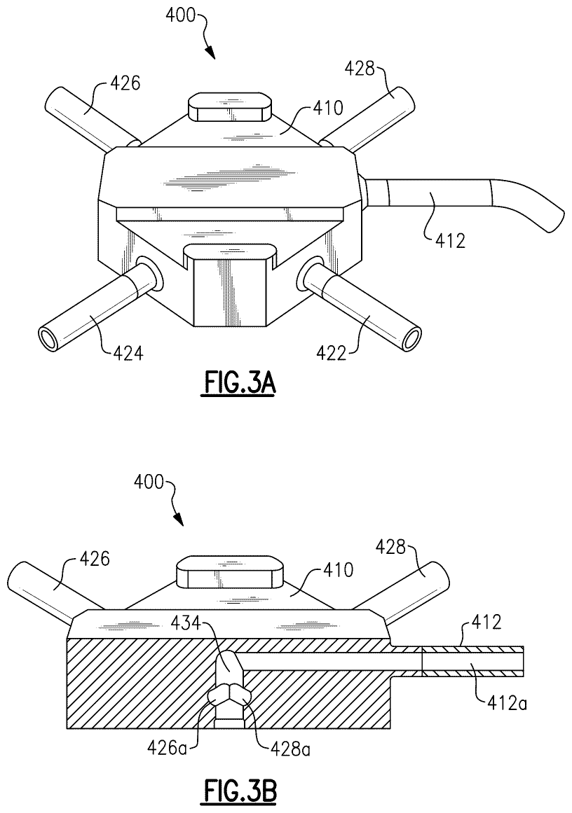

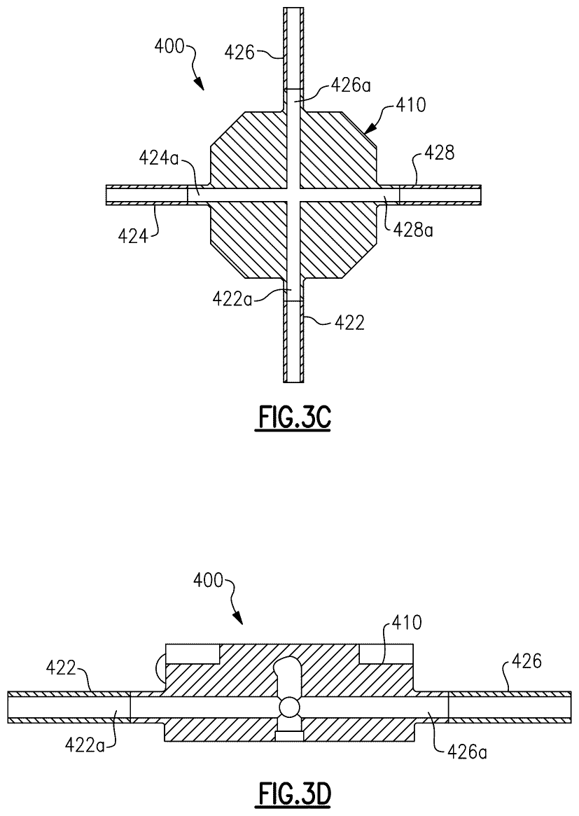

FIGS. 3A-3D illustrate a baseline model configuration for a gas hub manifold assembly according to embodiments. The manifold assembly 400 includes a hub reservoir 410 fluidically connected to and between a gas source and a plurality of thin film or wafer processing stations. The manifold assembly additionally includes an inlet connected to the hub reservoir and configured for receiving the gas, through an external inlet line extending in a lateral, e.g., axial, direction, into an internal reservoir volume of the hub reservoir in an axial direction. The manifold assembly additionally includes a plurality of radially directed outlet lines 422, 424, 426, 428 connected to the hub reservoir and configured for delivering the gas to the wafer processing stations located away from, e.g., surrounding, the hub reservoir.

FIG. 3A illustrates a perspective view of a gas hub manifold assembly 400 having hub reservoir 410 having an internal reservoir volume fluidically connecting an inlet line 412 to a plurality of outlet lines (e.g., four outlet lines) 422, 424, 426, 428. The channel of inlet inside the hub reservoir 410 has an L-shape having a horizontal line portion and a vertical line portion, wherein the vertical line portion has an inner open end and the horizontal line portion is located closer to the gas source. The hub reservoir 410 is shown on the outside to be shaped like a vertical short octagon column with a height smaller than base dimensions and with four larger outer vertical surfaces. However, embodiments are not so limited and the hub reservoir 410 can have other suitable outer shapes, e.g., cylinder or prism. Each of the outer vertical surfaces of the hub reservoir 410 illustrated in FIG. 3A has extending outward therefrom one of the outlet lines 422, 424, 426, and 428. The outlet lines 422, 424, 426, and 428 are positioned to have a rotational symmetry when the hub reservoir is rotated by 360°/n, where n is an integer. The n can correspond to the number of outlet lines corresponding to the number of processing stations or deposition chambers. For the embodiment illustrated in FIG. 3A, n is 4, and the angles between the adjacent outlet lines may be about 90°, or can have other values, e.g., depending on the orientation of the outer vertical surfaces. The number of outlet lines, n, may be less or more than four, and may be about evenly circumferentially distributed around the manifold housing 410, or distributed forming rotational symmetry, as described above. The inlet line 412 may extend angularly between any two of the outlet lines outlet lines 422, 424, 426, and 428. In the illustrated arrangement, the inlet line 412 is attached to the hub reservoir 410 about a bisecting direction between two of the plurality of outlet lines, e.g., between outlet lines 422 and 428, as shown in FIG. 3A.

The inlet line 412 and the outlet lines 422, 424, 426, 428 may be round or circular tubes each having an internal channel. The internal channels of the inlet and outlet lines may be round channels with a diameter in a range of about 0.1 in to 0.5 in, e.g., 2 mm, 3 mm, 4 mm, 5 mm, 8 mm, 10 mm, 12 mm, 15 mm, or in a range defined by any two of these values. The internal channels of the plurality of outlet lines 422, 424, 426, 428 may have the same size or the same diameter. This can be beneficial for consistent gaseous fluid delivery among the different outlet lines. If the internal channels of the inlet line 412 or the outlet lines 422, 424, 426, 428 are not round shaped, a relevant dimension may be the maximum distance from side to side of the cross-sectional shape and may have any value described above.

Referring to FIG. 3B, a perspective cross-sectional view of the internal fluid structure inside the hub reservoir o 410 shown in FIG. 3A is illustrated. The perspective view of FIG. 3B is shown with the manifold assembly 400 positioned at an angle to partially reveal the outlet lines 426a, 428a behind the inlet line 412. As shown in FIG. 3B, the inlet line 412 has an internal inlet channel 412a, which penetrates horizontally into the hub reservoir 410 from the right side to about a central areas. Then the internal inlet channel 412a makes an about right-angle turn forming an L-shape to go vertically downward forming a vertical channel 434, and directly connects to internal outlet channels (e.g., 426a and 428a), as shown in FIG. 3B. The inlet line 412 is disposed vertically above the outlet lines 422, 424, 426, 428. As illustrated, the internal reservoir volume is substantially limited to the vertical channel 434.

FIGS. 3C and 3D show top down and side cross-sectional views of the manifold assembly 400, respectively, revealing the internal fluid structure inside the manifold housing 410 described above with respect to FIGS. 3A and 3B. Since the inlet line 412 is disposed vertically above the outlet lines 422, 424, 426, 428, as described above, the inlet line 412 is not visible in the top-down cross-sectional view of FIG. 3C. Likewise, the vertical plane that the inlet line is on is at an angle with the vertical plant that the outlet lines 422, 426 are on, as can be seen in FIG. 3A. Consequently, the inlet line 412 is not visible in the side cross-sectional view of FIG. 3D. As shown in FIG. 3C, the outlet lines 422, 424, 426, 428 have a rotational symmetry about a central axis that is vertical to the paper plane. As shown in FIG. 3D, the outlet lines 422, 426 (and 424, 428) extend outward at about the same vertical height.

When a fluid (e.g., one of the precursors, RP gases or CP gases) flows from the inlet channel 412a into the outlet channels 422a, 424a, 426a, 428a, the fluid has a velocity and therefore carries momentum in the fluid flow direction. FIG. 4 illustrates a fluid velocity distribution graphical image inside the inlet channel 412a and the two outlet channels 422a and 426a. The graphical image of fluid velocity distribution is generated by a computational fluid dynamics (CFD) simulation software. A graphical image of a vertical plane coincident with a centerline of the inlet channel 412a is superimposed with a graphical image of a vertical plane coincident with a centerline of the outlet channels 422a, 426a, which are coincident with each other, to form the velocity distribution graphical image shown in FIG. 4. The velocity distribution inside the outlet channels 428a and 424a may be equivalent or similar to that in the outlet channels 422a and 426a, respectively. In FIG. 4, the difference in velocity is represented by color difference, as illustrated by the vertical velocity scale 432 on the left side, from blue color at the bottom to represent low fluid velocity (e.g., as low as 0 m/s) to red color at the top to represent high velocity (e.g., as high as 400 m/s).

As stated above, an objective of the gas hub manifold is to deliver equal amount of fluid, e.g., precursor or RP, into the plurality of processing stations that are connected to the different outlet lines, or in other words, to achieve spatial uniformity among the outlet lines for gas delivery. As shown in FIG. 4, when the fluid inside the inlet channel 412a makes a turn to go downward and splits to enter the outlet channels 422a, 426a, part of the fluid demonstrates high velocity in reddish color and part of the fluid has low velocity in bluish color. It will be appreciated that the momentum carried by the fluid is a vector pointing to the fluid flow direction. The high velocity portion of the fluid indicated by the reddish color starts at about the right end of the inlet channel 412a, curves downward, and enters the outlet channel 426a as high velocity zone 436. Inside the outlet channel 426a, there exists a low velocity zone 438, which is located above the high velocity zone 436. In comparison, the velocity profile in the outlet channel 422a, which is opposite the outlet channel 426a, is more uniform, as evident by the smaller color difference in the outlet channel 422a shown in FIG. 4. The net effect of the velocity distribution difference between the outlet channels 422a, 426a relates to a flow rate difference between within the outlet channels 422a and 426a. In some configurations, this flow rate difference can be significant. CFD simulation results indicate that for the manifold assembly 400 illustrated in FIGS. 3A-3D, the outlet channel 426a tends to deliver higher mas flow rate than the outlet channel 422a. Different types of fluids may behave differently. For example, certain precursors (e.g., NH₃) can have a much higher flow rate difference than that of another type of gas (e.g., N₂).

As used herein throughout the disclosure, a figure of merit that measures a degree of non-uniformity factor (NU) for a plurality of outlet lines and an inlet can be expressed as the following equation:

$$N U = \frac{max . mass flow rate - min . mass flow rate}{inlet mass flow rate}$$

where max. flow rate refers to the highest flow rate among the plurality of outlet lines; min. flow rate refers to the lowest flow rate among the plurality of outlet lines; and inlet mass flow rate refers to the flow rate into the inlet line. The CFD simulation shows that the non-uniformity factor (NU) observed for the baseline model manifold assembly illustrated in FIGS. 3A-3D can be more than 1%, and can reach as high as about 5%. Flow rate difference between the different outlet channels may cause unacceptable difference in thin film deposition rates in the deposition chambers that are connected to the different outlet channels.

To address these and other needs, in the following, various improvements over the baseline model configuration are described. Various design improvements of the gas hub manifold assembly for delivering a gas to multi-station wafer processing system includes a hub reservoir fluidically connected to and between a gas source and a plurality of wafer processing stations. The manifold assembly additionally includes an inlet connected to the hub reservoir and configured for receiving the gas into the hub reservoir in an axial direction. The manifold assembly additionally includes a plurality radially directed of outlet lines connected to the hub reservoir and configured for delivering the gas to the respective wafer processing stations, e.g., surrounding the hub reservoir. In some improved designs, an internal reservoir volume of the hub reservoir lacks rotational symmetry when the hub reservoir is rotated about a central axis of the hub reservoir by any angle less than 360°. In some other improved designs, an internal reservoir volume of the hub reservoir has an uppermost surface, and the inlet is configured to introduce the gas at a lower vertical level below the uppermost surface. In some other improved designs, a hub reservoir provides an internal reservoir volume of at least 10,000 mm³.

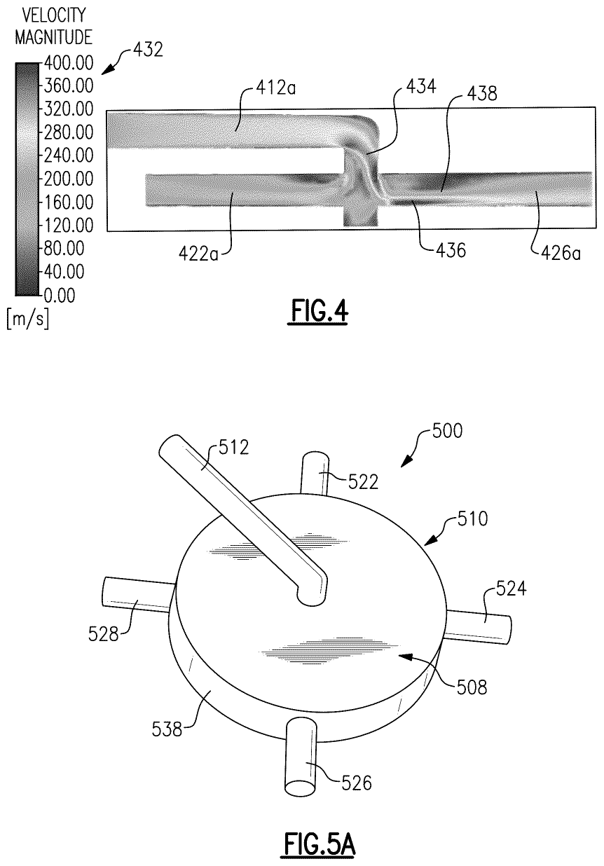

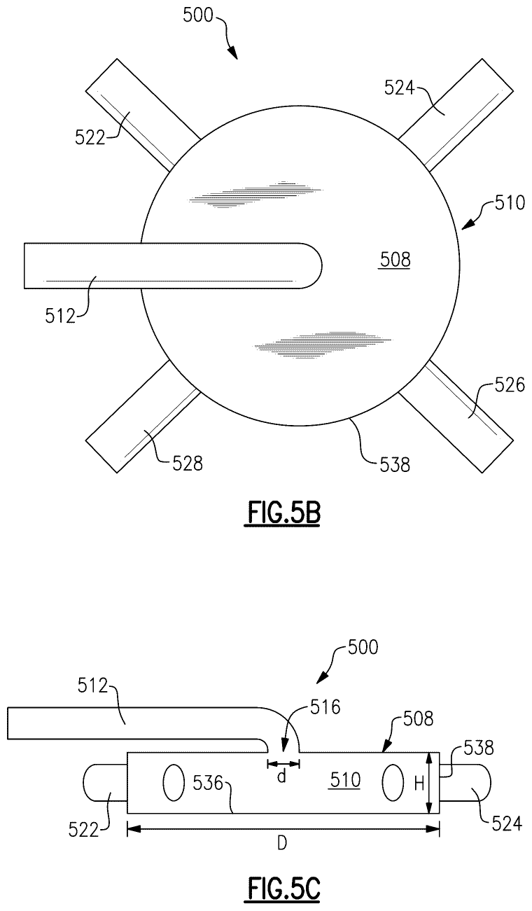

FIGS. 5A-5C illustrate a manifold assembly 500 having substantially increased an internal reservoir volume thereof. FIG. 5A is a perspective view of an internal reservoir volume of a gas hub reservoir 510 fluidically connected to an inlet line 512 and a plurality of outlet lines (e.g., four outlet lines) 522, 524, 526, and 528. For clarity, an outer housing for forming the hub reservoir 510 inside is not illustrated in FIG. 5A, and in FIGS. 5B-5C. The structure of the manifold assembly 500 is similar in some respects to that of the manifold assembly 400 described above with respect to FIGS. 3A-3D for receiving a gas and distributing the gas to multiple processing stations, and the similarities may not be repeated herein for brevity. Unlike the manifold assembly 400, the manifold assembly 510 includes a substantially increased internal reservoir volume. To increase the internal reservoir volume, the hub reservoir 510 has a vertically erected cylindrical shape with a diameter of a circular base 536 that expands much greater in dimension relative to a reservoir height. However, embodiments are not so limited and the internal reservoir volume of the hub reservoir 510 may take other shapes, e.g., polygonal prism, trapezoidal column, barrel shaped column that has a larger middle section, etc. Accordingly, the base 536 may take the shape of a circle or round area, a polygonal area, etc. On a top or uppermost surface 508 of the hub reservoir 510 the inlet line 512 is connected, at about a centered position in the uppermost surface 508. The outer shape of the housing of the internal hub reservoir 510 can resemble the shape of the hub reservoir 510, or can take another shape. For example, when the hub reservoir 510 is a cylindrical column, the outer shape of the housing can take a shape of a polygonal prism, a barrel shaped column, or another suitable shape.

According to various embodiments, the hub reservoir has an internal reservoir volume of at least 10,000 mm³, 12,000 mm³, 14,000 mm³, 16,000 mm³, 18,000 mm³, 20,000 mm³, 22,000 mm³, 24,000 mm³, 26,000 mm³ or a value in a range defined by any of these values. The flow rate from the inlet line 512 through the hub reservoir 510 and exiting the outlet lines 522, 524, 526, 528 may be up to 25,000 sccm.

A top view of the internal reservoir volume of the hub reservoir 510 is illustrated in FIG. 5B. The outlet lines 522, 524, 526, 528 are positioned to have a rotational symmetry when the hub reservoir is rotated by 360°/n, where n is an integer. The integer n can correspond to the number of outlet lines, which in turn corresponds to the number of thin film processing stations or chambers. As can be seen, the four outlet lines 522, 524, 526, 528 are connected to the hub reservoir 510 at a sidewall (or sidewalls). In other words, the four outlet lines 522, 524, 526, 528 are about equally spaced circumferentially around the hub reservoir 510, with each outlet line extending in a radial direction passing through a center of the hub reservoir 510. Therefore, the angle between the adjacent outlet lines, as shown in FIG. 5B, is about 90°. There can be more or less than four outlet lines. However, they may be about evenly distributed around the circumference of the hub reservoir 510, or form a rotational symmetry about the center of the hub reservoir 510. As shown in FIG. 5B, the inlet line 512 extends laterally and axially toward the center area of the uppermost surface 508, and may be arranged about halfway between two of the plurality of outlet lines, e.g., about half way between the outlet lines 522 and 528. The inlet line 512 may also be in line with one of the outlet lines 522, 524, 526, 528, or at another angular position. The inlet line 512 and outlet lines 522, 524, 526, 528 may be round tubes each having a round internal channel. The internal channels of the inlet and outlet lines may be round shaped with a diameter in a range of about 0.1 in to 0.5 in, e.g., 2 mm, 3 mm, 4 mm, 5 mm, 8 mm, 10 mm, 12 mm, 15 mm, or may be in a range, or even outside of the range, defined by these values. The internal channels for the plurality of outlet lines 522, 524, 526, 528 may share the same size. The inlet and outlet lines and their internal channels can take shapes other than cylindrical or round channels.

FIG. 5C is a cross-sectional view of the cylindrical shaped internal reservoir volume of the hub reservoir 510, which is characterized by the round base 536 having a diameter D and surrounded by a cylindrical sidewall 538. The internal channel of the inlet line 512 runs horizontally from upper left to about a central area of the hub reservoir 510 and makes a turn to go vertically downward, reaching inside the hub reservoir 510. An inner open end 516 of the inlet line 512 has a diameter d. FIG. 5C also shows that the outlet lines 522, 524 are connected to the hub reservoir 510. The outlet lines 528, 526 are opposite of the outlet lines 522, 524, and are not visible in FIG. 5C.

A greater D/d ratio means that the inner open end 516 of the inlet line 512 is disposed in a significantly wider hub reservoir 510. Greater D/d value corresponds to greater lateral space inside the hub reservoir 510 surrounding the inner open end 516. As such there is more distance for the momentum of the fluid coming out of the inner open end 516 be absorbed before the fluid reaches one of the outlet lines 522, 524, 526, 528, consequently improving gas delivery uniformity and reducing the non-uniformity factor NU. The diameter of the base 536, D, can be at least 3 times greater than the diameter of the inner open end 516, d, thus a D/d ratio of more than 3. The diameter of the inner open end 516, d, can be in a range of 1 mm-10 mm, or larger. For various embodiments, the D/d ratio may be 5 or greater, for example, 8 or greater, 10 or greater, 15 or greater.

In addition to the increased internal reservoir volume, the inventors have discovered that the shape of the internal reservoir volume of the hub reservoir can be important for improving the non-uniformity factor NU. In particular, the inventors have found that station-to-station gas delivery uniformity is improved when the entry point of the inlet (e.g., inner open end 516 of the inlet line 512) into the internal reservoir volume is below a uppermost surface 508 of the hub reservoir 512, and reaches an optimal point when the inner open end 516 is located about half way between the uppermost surface 508 and the base 536. In addition, the station-to-station gas delivery uniformity is improved when the hub reservoir 510 is asymmetric. This may be because the inlet line 512 comes asymmetrically from one side of the hub reservoir 510.

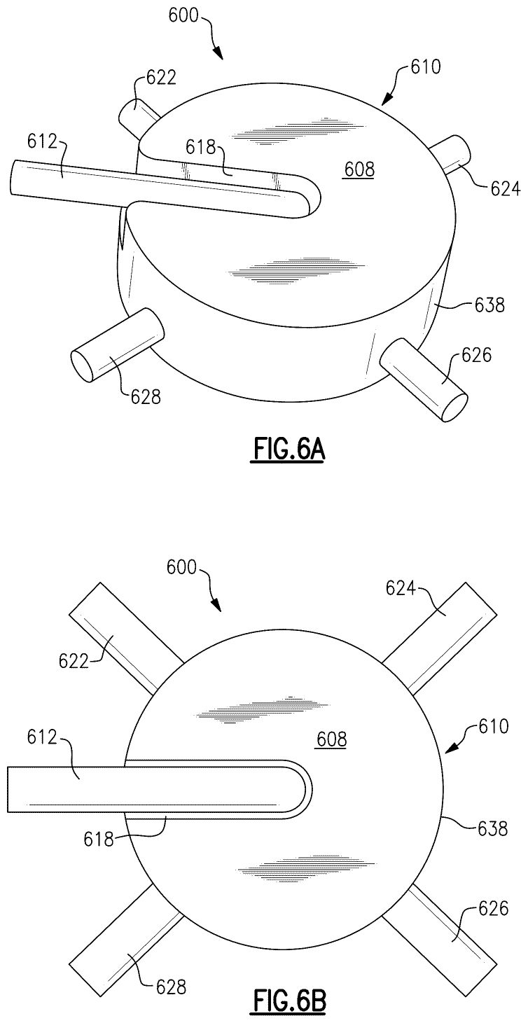

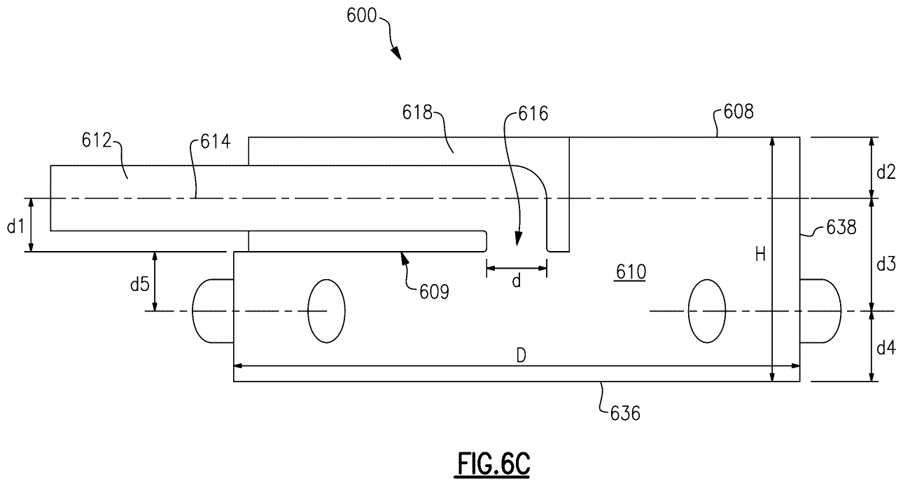

FIGS. 6A-6C show an embodiment where a manifold assembly 600 has certain improved features based on the descriptions above with respect to FIGS. 5A-5C. As described above with respect to FIGS. 5A-5C, the illustrated embodiment in FIGS. 6A-6C has the internal reservoir volume of the hub reservoir 610 that connects inlet line 612 and outlet lines 622, 624, 626, 628. As described above with respect to the manifold assembly illustrated in FIGS. 5A-5C, the outer shape and configuration of the manifold assembly 600 are not illustrated for clarity. Description for some features of the manifold assembly 600 that are substantially the same as those of the manifold assembly 500 illustrated in FIGS. 5A-5C are omitted for brevity. As illustrated, the internal reservoir volume of the hub reservoir 610 lacks rotational symmetry when the hub reservoir 610 is rotated about a central axis of the hub reservoir 610 by any angle less than 360°. In addition, the hub reservoir 610 has an uppermost surface 608, and the inlet line 612 is configured to introduce a gas into the hub reservoir 610 at a vertical level below the uppermost surface 608. These features are achieved by providing an elongated groove or trench 618 formed in the uppermost surface 608 of the hub reservoir 510 to house the inlet line 512 therein. The elongated groove or trench 618 extends from a central region of the hub reservoir 610 to a circumferential sidewall 638 of the hub reservoir 610, and as such makes the circumferential sidewall 638 making a non-uniform height. In some embodiments, the hub reservoir 610 has a round shape defining a circular reservoir base 636. In this case, the circumferential wall 638 forms a cylindrical sidewall. As described above, the positioning of the inlet line 612 below the uppermost surface 608 and the asymmetry of the hub reservoir 610 are advantageous for improved spatial gas delivery uniformity among the outlet lines 622, 624, 628, and 628.

A cross-sectional view of the manifold assembly 600 shown in FIGS. 6A-6B is illustrated in in FIG. 6C. As shown in FIG. 6C, an inner open end 616 is disposed about the central region of the hub reservoir 610 laterally and vertically. In some embodiments, the hub reservoir 610 may be constructed so that a diameter of the inner open end 616 is a significantly smaller than the lateral dimension of the hub reservoir 610, as described above with respect to FIG. 5C. As such when the gas comes out of the inner open end 616, there is sufficiently long distance in the flow direction to dissipate the momentum before reaching one of the outlet lines.

The inventors have discovered that various dimensional parameters shown in FIG. 6C can have significant impact on the gas delivery uniformity. The design parameters include a vertical distance d2 between the topmost surface 608 of the hub reservoir 610 and a axial centerline 614 of the inlet line 612, a vertical distance d3 between the centerline 614 and a horizontal plane coincident with centerlines of the outlet lines 622, 624, 626, 628, a vertical distance d4 between the horizontal plane coincident with the outlet lines 622, 624, 626, 628 and the reservoir base 636 of the hub reservoir 610, a vertical distance d1 between the axial centerline 614 of the inlet line 612 and an intermediate upper horizontal plane 609 that is at the same height of the inner open end 616 of the inlet line 612 formed in the horizontally elongated groove or trench 618, and a vertical distance d5 between the inner open end 616 of the inlet line 612 and the horizontal plane coincident with the outlet lines 622, 624, 626, 628. As illustrated in FIG. 6C, an overall height of the hub reservoir 610, which is the height of the sidewall 638, is the summation of d2, d3, and d4. Further, the inner open end 616 of the inlet line 612 is disposed at the intermediate upper plane 609, which is below the uppermost surface 608 by a distance that is a summation of d1 and d2. As described above, the inventors have found that bringing the inner open end 616 of the inlet line 612 below the uppermost surface 608 improves the uniformity of gas delivery to multiple processing stations through the outlet lines 622, 624, 626, 628.

TABLE 1
Design Parameters for Various Analysis Configurations

| | | | | | | | | Internal |
|---|---|---|---|---|---|---|---|---|
| | | | | | | | | Reservoir |
| | d1 | d2 | d3 | d4 | d5 | d2/ | d4/ | Volume |
| Design | (mm) | (mm) | (mm) | (mm) | (mm) | (d2 + d3 + d4) | (d2 + d3 + d4) | (mm³) |
| Base V2 | 3.714 | 2.286 | 8 | 5 | 4.286 | 0.14954861 | 0.32709669 | 21009 |
| New V1 | 3.714 | 2.286 | 8 | 5 | 4.286 | 0.14954861 | 0.32709669 | 20238 |
| New V2 | 3.714 | 4.286 | 8 | 5 | 4.286 | 0.24794631 | 0.28925142 | 23511 |
| New V3 | 5.714 | 2.286 | 8 | 5 | 2.286 | 0.14954861 | 0.32709669 | 20596 |
| New V4 | 3.714 | 2.286 | 8 | 3 | 4.286 | 0.17206082 | 0.2258016 | 18105 |
| New V5 | 3.714 | 5.286 | 8 | 5 | 4.286 | 0.28907361 | 0.27343323 | 24762 |
| New V6 | 3.714 | 2.286 | 8 | 7 | 4.286 | 0.13224575 | 0.40495198 | 23914 |
| New V7 | 6.714 | 2.286 | 11 | 5 | 4.286 | 0.12501367 | 0.27343323 | 24762 |
| New V8 | 7.714 | 2.286 | 12 | 4 | 4.286 | 0.12501367 | 0.21874658 | 24560 |
| New V9 | 3.714 | 6.286 | 8 | 4 | 4.286 | 0.34376025 | 0.21874658 | 24560 |

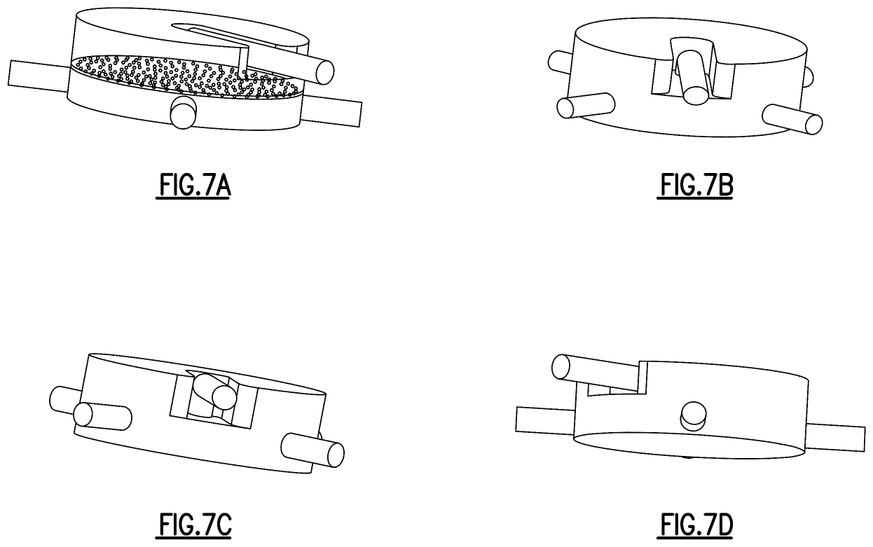

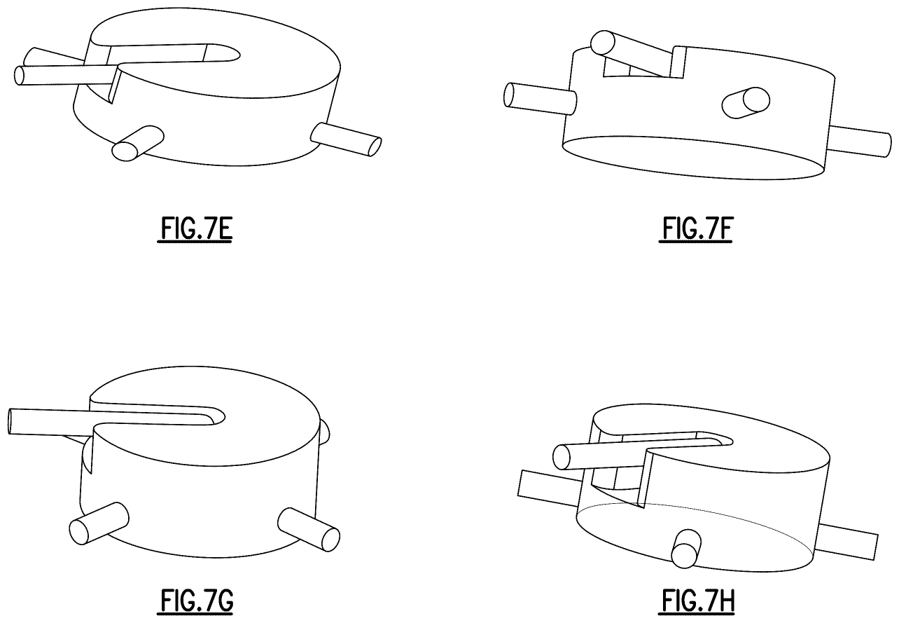

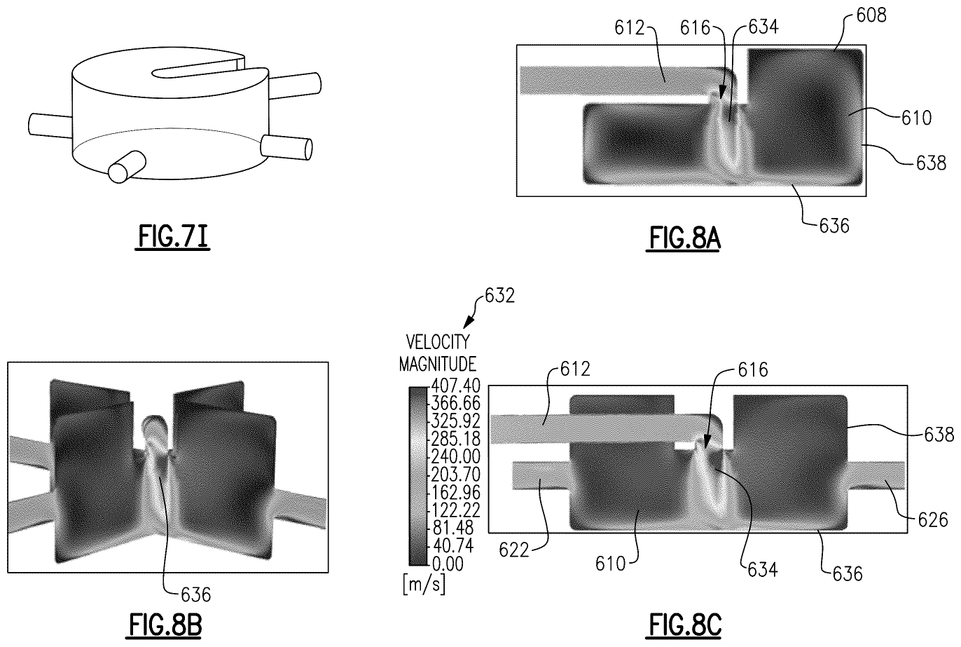

The inventors have therefore designed various hub reservoir configurations with the different values of d1, d2, d3, d4 and d5, as shown in TABLE 1 below, for CFD simulation analysis. Starting with an improved base design (“Base V2”) described with respect to FIGS. 6A-6C, various design configurations New V1-New V9, as illustrated in FIGS. 7A-7I, respectively, have been constructed and analyzed with. The parameters listed in TABLE 1 and the illustrations of FIGS. 7A-7I reveal the differences of the various design configurations for simulation analysis.

All the manifold configurations listed in TABLE 1, including Base V2 and New V1-New V9, share common features. An inlet line extends horizontally and laterally to the center of the hub reservoir and turns vertically downward to enter the hub reservoir. The inlet line is disposed in a trench formed in an uppermost surface of the hub reservoir, and the inlet line is located vertically below the uppermost surface. Consequently, the hub reservoir has an asymmetric shape when turning around the center. Another common feature is that each of the manifold configurations has four outlet lines radially connected to the hub reservoir as shown in FIGS. 6A-6C.

Except for the common features described above, all the dimensional changes of the configurations, including d1, d2, d3, d4 and d5, are in the vertical direction. For two critical parameters of the configurations, d1 and d4 may be both configured in a range of 1 mm-10 mm. The Base V2 configuration listed in TABLE 1 is the configuration that other manifold configurations, e.g., New V1-New V9, are compared to. New V1 has the same dimensional configurations of Base V2, but includes a diffuser plate in the reservoir located vertically between the inlet line and the outlet lines. New V2 has the uppermost surface raised by 2 mm compared to Base V2, namely increasing d2 by 2 mm. New V5 raised the uppermost surface by 3 mm. Raising the uppermost surface without changing other parameters increases the internal reservoir volume and locates the inner open end of the inlet line closer to the center of the hub reservoir in the vertical direction. For example, for New V5, the inner open end of the inlet line is located (d1+d2)=9 mm below the uppermost surface of the reservoir, comparing to the overall height of the reservoir of H=(d2+d3+d4)=18.286 mm. Measured from the axial centerline 614, the inner open end of the inlet line is located d2=2.286 mm below. Therefore, the inner open end of the inlet line is vertically disposed 49.2% of the reservoir height measured from the uppermost surface and 12.5% measured from the axial centerline, very close to the vertical center of the reservoir.

As shown in FIGS. 7A-7I and TABLE 1, New V3 moves the inner open end of the inlet line lower by 2 mm without changing other dimensions. New V4 moves the base of the reservoir up by 2 mm without changing other dimensions, effectively shrinking the internal reservoir volume. In comparison, New V6 moves the base of the reservoir down by 2 mm without changing other dimensions, effectively increasing the internal reservoir volume. But the change of New V6 also makes the inner open end of the inlet line further away from the vertical center of the hub reservoir. Further, New V7 moves both the uppermost surface and the center line of the inlet line up by 3 mm. This changes have similar effects of New V5 for increasing reservoir volume and centering the inner open end of the inlet line. New V8 moves both inlet line (e.g., centerline) and the uppermost surface up by 4 mm, and moves reservoir base up by 1 mm. Lastly, New V9 moves the uppermost surface up by 4 mm without moving the inlet line, and moves reservoir base up by 1 mm.

The inventors conducted CFD simulation for the manifold configurations, New V1-New V9, listed in TABLE 1 and illustrated in FIGS. 7A-7I. A common inlet mass flow rate of 0.375028 g/s and fluid property of N₂ are applied for the simulation analyses. As shown in TABLE 2 below, mass flow rates for the four outline lines, Outlet 1, Outlet 2, Outlet 3, and Outlet 4, are output from the CFD simulation for each of the manifold configurations, New V1-New V9. Then, Mass Flow Rate Range is calculated as (max. mass flow rate−min. mass flow rate), and NU is calculated according to the equation listed above. As shown in TABLE 2, New V5 has the lowest NU value, thus the best performance of gas delivery uniformity to multiple processing stations.

TABLE 2
Simulation Results for Designs Configurations of FIG. 7A-7I

| Mass Flow | | | | | |
|---|---|---|---|---|---|
| Rate (g/s) | New V1 | New V2 | New V3 | New V4 | New V5 |
| Outlet 1 | 0.095830 | 0.094242 | 0.095056 | 0.092945 | 0.094005 |
| Outlet 2 | 0.095799 | 0.094142 | 0.094847 | 0.092713 | 0.093887 |
| Outlet 3 | 0.091700 | 0.093247 | 0.092590 | 0.094794 | 0.093696 |
| Outlet 4 | 0.091698 | 0.093397 | 0.092535 | 0.094576 | 0.09344 |
| Mass Flow | 0.004132 | 0.000995 | 0.002521 | 0.002081 | 0.000566 |
| Rate Range | | | | | |
| NU | 1.102% | 0.265% | 0.672% | 0.555% | 0.151% |

| Mass Flow | | | | |
|---|---|---|---|---|
| Rate (g/s) | New V6 | New V7 | New V8 | New V9 |
| Outlet 1 | 0.095956 | 0.093420 | 0.093533 | 0.092714 |
| Outlet 2 | 0.095851 | 0.093334 | 0.093410 | 0.092503 |
| Outlet 3 | 0.091682 | 0.094219 | 0.094127 | 0.094952 |
| Outlet 4 | 0.091540 | 0.094055 | 0.093958 | 0.094859 |
| Mass Flow | 0.004416 | 0.000885 | 0.000717 | 0.002449 |
| Rate Range | | | | |
| NU | 1.178% | 0.236% | 0.191% | 0.653% |

The inventors have discovered that a ratio of d2 to the overall height (d2+d3+d4) can be an important parameter for reducing non-uniformity. The inventors have further discovered that a ratio of d4 to the overall height (d2+d3+d4) can be an important parameter for reducing non-uniformity. The inventors have particularly discovered that the ratio d2/(d2+d3+d4) and/or the ratio d4/(d2+d3+d4) should be 0.10-0.12, 0.12-0.14, 0.14-0.16, 0.16-0.18, 0.18-0.20, 0.20-0.22, 0.22-0.24, 0.24-0.26, 0.26-0.28, 0.28-0.30, 0.30-0.32, 0.32-0.34, 0.34-0.36, 0.36-0.38, 0.38-0.40, 0.40-0.42 or a value in a range defined by any of these values. As shown by the simulation results, a difference between these two ratios may also be a consideration. Depending on the value of flow rate and nonuniformity, a combination of d2/(d2+d3+d4) and d4/(d2+d3+d4) can be chosen for optimum design. In some embodiments, the height of the outlet channels relative to the reservoir base may be considered. The outlet channels may be located about half way between the reservoir base and the inner open end of the inlet line (e.g., about 40%-60% of the vertical distance from the base to the inner open end).

Fluid velocity distribution graphical images inside the hub reservoir 610 shown in FIGS. 6A-6C and the connected fluid lines are illustrated in FIGS. 8A-8C. The graphical images of fluid velocity is generated by the computational fluid dynamics (CFD) simulation software as described above. In FIG. 8A the graphical image of fluid velocity distribution is taken from a vertical plane coincident with the centerline of the inlet line 612. In FIG. 8B the graphical images of fluid velocity distribution of two vertical planes are presented, with a vertical plane coincident with the centerline of the outlet lines 622-626 and the other vertical plane coincident with the centerline of the outlet lines 624-628. In FIG. 8C, the graphical image shown in FIG. 8A is superimposed with the graphical image shown in FIG. 8B for the vertical plane the outlet lines 622-626. The velocity difference in FIGS. 8A-8C is represented by color difference, as illustrated by the vertical velocity scale 632 shown in FIG. 8C, from blue at the bottom to represent low fluid velocity (e.g., 0 m/s) to red at the top to represent high velocity (e.g., 407.4 m/s).

As shown in FIGS. 8A-8C, when the fluid makes a turns at the right end of the inlet channel 612 to go downward and enters into the hub reservoir 610, a high velocity zone 634 is developed, which is represented by red and yellowish color. Surrounding the high velocity zone 634 is a green zone indicating medium fluid velocity (e.g., from 150 m/s to 250 m/s). Further away from the high velocity zone 634 is a significantly larger surrounding lower velocity or stagnant fluid zone indicated by bluish color. According to the velocity magnitude scale 632, the fluid velocity in the low velocity zone can be lower than 50 m/s, or even approaching 0 m/s in isolated regions. The bluish color low velocity zone further indicates that the zone surrounding the central high velocity zone 634 has about uniform fluid pressure or small pressure gradient. It will be appreciated that a pressure difference in a fluid causes the fluid to flow. As such, small pressure gradient in a fluid means the fluid is about stagnant. Close to the sidewall 638 and before entering each entrance of the outlet lines, fluid velocity remains low (e.g., less than 150 m/s), according to the color scale shown in FIG. 8C. More importantly, the fluid velocity at the entrances of the outlet channel 622, 626 as indicated by their colors are almost equivalent to each other. This equivalency continues in the three outlet lines that are visible in the figures, including the outlet lines 622, 626. The velocity equivalency in the outlet lines leads to mass flow rate equivalency, and thus to high gas delivery uniformity among the outlet lines.

In summary, when the fluid flows in the inlet line 612 and enters the hub reservoir 610 at the inner open end 616, it enters into a much wider space defined by the base 636 with a height defined by the sidewall 638. The momentum of the fluid comes out of the inner open end 616 can be quickly dissipated into the surrounding fluid in the hub reservoir 610.

The uniform pressure distribution at the sidewall is advantageous for consistent delivery of flow rate to different outlet lines that are connected to the hub reservoir 610, thus better uniformity performance. The CFD simulation results indicate that for the improved manifold assemblies illustrated in FIGS. 5A-7I, the gas delivery uniformity among the outlet lines is much better than gas delivery uniformity of the baseline model manifold assembly 400 shown in FIGS. 3A-3D. Simulations have been performed for different fluids, which have different fluid properties to cause different behaviors, and produced consistent results compared with the simulation results listed in TABLE 2 for nitrogen (N₂). Other fluids include titanium tetrachloride (TiCl₄), chlorine trifluoride (CIF₃), continuous purge nitrogen (CP N₂), ammonia (NH₃), and argon (Ar).

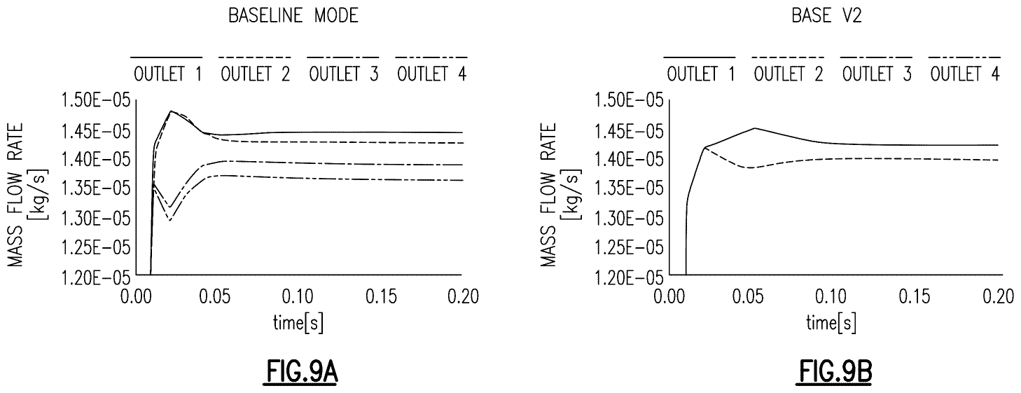

FIGS. 9A-9B illustrate mass flow rate curves as a function of time for the outlet lines of the baseline model manifolds 400 shown in FIGS. 3A-3D and the improved manifold assembly 600 shown in FIGS. 6A-6C. As can be seen, the improved manifold assembly 600 performs much better than the baseline model manifold assembly 400, especially when the time is within 0.05 seconds. The maximum mass flow rate range among the outlet lines of the baseline model manifolds 400 reaches 27%, compared to less than 16% for the improved manifold assembly 600. The mass flow rate range for the improved manifold assembly 600 remains significantly better than the baseline model manifolds 400 after about 0.08 seconds. Thus, the improved manifold assembly 600 performs significantly better than the baseline model manifolds 400 for temporal uniformity.

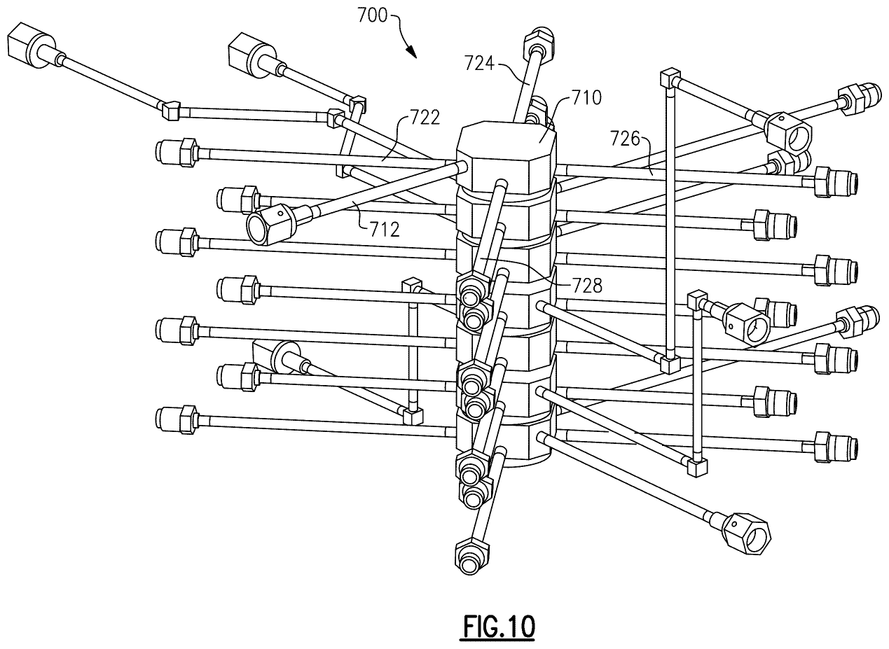

FIG. 10 shows seven manifold assemblies stacked on top of one other. The stack of manifolds can be disposed at a central location of a deposition system, in a similar manner as shown for the gas hub manifolds 136 described above with respect to FIG. 2. In FIG. 10, only the top manifold assembly 700 is labeled with numerals. But the other six manifold assemblies are the same or similar to the top manifold assembly 700, each having a manifold housing 710 having a hub reservoir formed therein connected to an inlet line 712, and four outlet lines 722, 724, 726, 728. The hub reservoir of the manifold assembly 700 may be the same as the hub reservoir 610 of the manifold assembly 600 shown in FIGS. 6A-6C, or one of the manifold configurations shown in FIGS. 7A-7I for achieving high special uniformity for delivering a gas to multiple wafer processing stations. Each of the manifold assemblies in FIG. 10 has an asymmetric hub reservoir, and the inlet line is vertically located below an uppermost surface of the reservoir. Each of the hub reservoir has a volume of at least 10,000 mm³.

Because for each of the manifold assemblies in FIG. 10 the horizontal inlet line is buried under the uppermost surface of the hub reservoir, each manifold assembly has a short prism outer shape. This ensures that when the manifold assemblies are stacked together, a compact overall height of the stacked manifold assemblies is achieved.

Other factors may be critical for delivering consistent dosage to the plurality of deposition chambers fluidically connected to manifold 500. It will be appreciated that the flow rate may be reversely proportional to pressure drop (or fluid resistance). Pressure drop is the difference of the fluid pressure in the manifold and the fluid pressure in the processing station or deposition chamber that the fluid is delivered to. As discussed above, the manifold assembly 700 can ensure about uniform fluid pressure inside the hub reservoir 530. Therefore, it is important to implement the fluid delivery lines from the hub reservoir 710 to each of the deposition chambers for consistent precursor or purge gas flow rate or dosage. For example, the diameter and the length of each delivery line from the hub reservoir 710 to respective the deposition chamber, the number of bends in the delivery lines, and the ALD valve flow coefficient are important factors to be considered to determine the fluid resistance in the delivery line. CFD simulation or experiment may be performed to ensure that the fluid resistance in each of the outlet channels is equivalent to each other for consistent flow rate or dosage. According to FIG. 1, the pressure inside each deposition chamber 103 can be monitored by the pressure monitoring sensor P.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and sub-combinations of features of this disclosure are intended to fall within the scope of this disclosure.

What is claimed is:

1. A gas hub manifold assembly for delivering a gas to a multi-station wafer processing system, the manifold assembly comprising:
a hub reservoir fluidically connected to and between a gas source and a plurality of wafer processing stations;
an inlet connected to the hub reservoir and configured for receiving the gas into an internal reservoir volume of the hub reservoir in an axial direction; and
a plurality radially directed outlet lines connected to the hub reservoir and configured for delivering the gas to the plurality of wafer processing stations,
wherein the internal reservoir volume of the hub reservoir lacks rotational symmetry when the hub reservoir is rotated about a central axis of the hub reservoir by any angle less than 360°.

2. The manifold assembly of claim 1, wherein the outlet lines are positioned to have a rotational symmetry when the hub reservoir is rotated by 360°/n, where n is an integer.

3. The manifold assembly of claim 2, wherein n is the number of outlet lines.

4. The manifold assembly of claim 3, wherein n is 4.

5. The manifold assembly of claim 1, wherein the internal reservoir volume of the hub reservoir has a circular base and a cylindrical sidewall, wherein the cylindrical sidewall has a non-uniform height.

6. The manifold assembly of claim 5, wherein a diameter of the circular base is at least 3 times greater than a diameter of the inlet.

7. The manifold assembly of claim 6, wherein the diameter of the circular base is between 20 mm and 60 mm.

8. A gas hub manifold assembly for delivering a gas to a multi-station wafer processing system, the manifold assembly comprising:
a hub reservoir fluidically connected to and between a gas source and a plurality of wafer processing stations;
an inlet connected to the hub reservoir and configured for receiving the gas into an internal reservoir volume of the hub reservoir in an axial direction, wherein the internal reservoir volume of the hub reservoir has an uppermost surface, and the inlet is configured to introduce the gas at a vertical level below the uppermost surface; and
a plurality radially directed outlet lines connected to the hub reservoir and configured for delivering the gas to the plurality of wafer processing stations surrounding the hub reservoir.

9. The manifold assembly of claim 8, wherein the outlet lines are positioned to have a rotational symmetry when the internal reservoir volume is rotated by 360°/n, wherein n is the number of outlet lines.

10. The manifold assembly of claim 9, wherein n is 4.

11. The manifold assembly of claim 8, wherein the internal reservoir volume has a circular base and a cylindrical sidewall, wherein the cylindrical sidewall has a non-uniform height.

12. The manifold assembly of claim 8, wherein an uppermost surface of the internal reservoir volume comprises a circular surface and an elongated trench extending from a central region to a circumferential sidewall thereof.

13. The manifold assembly of claim 11, wherein the inlet has an inner open end opening into a central region of the internal reservoir volume of the hub reservoir.

14. The manifold assembly of claim 13, wherein the inner open end opens into the central region of the internal reservoir volume through an intermediate upper plane thereof that is at a vertical level below the uppermost surface of the internal reservoir volume.

15. The manifold assembly of claim 14, wherein the inlet disposed inside the hub reservoir has an L-shape having a horizontal line portion and a vertical line portion, wherein the vertical line portion has the inner open end, and the horizontal line portion is closer to the gas source.

16. The manifold assembly of claim 15, wherein a ratio between a vertical distance between a horizontal axis of the horizontal line portion and the intermediate upper plane of the internal reservoir volume to a maximum height of the cylindrical sidewall is in a range of about 10% to 60%.

17. The manifold assembly of claim 16, wherein the ratio is in a range of about 20% to 50%.

18. The manifold assembly of claim 8, wherein the outlet lines are disposed at about a horizontal plane located vertically above a reservoir base of the internal reservoir volume.

19. A gas hub manifold assembly for delivering a gas to a multi-station wafer processing system, the manifold assembly comprising:
a hub reservoir fluidically connected to and between a gas source and a plurality of wafer processing stations and provides an internal reservoir volume of at least 10,000 mm³;
an inlet connected to the hub reservoir and configured for receiving the gas into the internal reservoir volume of the hub reservoir in an axial direction; and
a plurality radially directed of outlet lines connected to the hub reservoir and configured for delivering the gas to the wafer processing stations surrounding the hub reservoir.

20. The manifold assembly of claim 19, wherein the wafer processing stations are configured for processing 300 mm substrates.

21. The manifold assembly of claim 19, wherein the internal reservoir volume is configured to flow the gas therethrough at a flow rate up to 25,000 sccm.

22. The manifold assembly of claim 19, wherein the internal reservoir volume of the hub reservoir lacks rotational symmetry when the hub reservoir is rotated about a central axis of the hub reservoir by any angle less than 360°.

23. The manifold assembly of claim 19, wherein the plurality of outlet lines is about evenly distributed around a circumference of the internal reservoir volume.

24. The manifold assembly of claim 19, wherein the outlet lines are positioned to have a rotational symmetry when the internal reservoir volume is rotated by 360°/n, where n is the number of outlet lines.

25. The manifold assembly of claim 24, wherein n is 4.

26. The manifold assembly of claim 19, wherein the processing stations are configured for depositing a thin film on a substrate.

27. The manifold assembly of claim 19, wherein the internal reservoir volume has an uppermost surface and an intermediate upper plane disposed at a lower vertical level below the uppermost surface, and wherein the inlet is configured to introduce the gas into the hub reservoir through the intermediate upper plane.

28. The manifold assembly of claim 27, wherein the inlet disposed inside the hub reservoir has an L-shape having a horizontal line portion and a vertical line portion, wherein the vertical line portion has an inner open end fluidically connected to the hub reservoir and the horizontal line portion is closer to the gas source.

29. The manifold assembly of claim 28, wherein a vertical distance between a horizontal axis of the horizontal line portion and the intermediate upper plane of the internal reservoir volume is about 1-10 mm.

30. The manifold assembly of claim 21, wherein the outlet lines are disposed at about a horizontal plane located vertically above a reservoir base of the internal reservoir volume, and wherein a vertical distance between the horizontal plane and the reservoir base of the internal reservoir volume is about 1-10 mm.
